(19) United States
(12) Patent Application Publication
(10) Pub. No.: US 2009/0225511 A1
(43) Pub. Date: Sep. 10, 2009

(54) HEAT SINK MODULE

(75) Inventors: Ting-Wei Hsu, Taipei City (TW); Ming-Shing Kao, Kaohsiung City (TW)

Correspondence Address: Ting-Wei Hsu, P.O.BOX 108-00403, Taipei, 106, omitted

(73) Assignee: Ting-Wei Hsu, Taipei City (TW)

(21) Appl. No.: 12/125,076

(22) Filed: May 22, 2008

(30) Foreign Application Priority Data
Mar. 7, 2008 (TW) 097203941

(51) Int. Cl. H05K 7/20

(52) U.S. Cl. 361/697

(57) ABSTRACT

A heat sink module for heat dissipating is disclosed. The heat sink module comprises a heat sink plate and a fan assembly. The heat sink plate is installed above a heat source and has a plurality of heat sink fins and a receiving space. The fan assembly is positioned near the receiving space, and has a first fan, at least one second fan coaxially connected to the first fan by a core shaft extending downwardly from the first fan, and a drive unit connected to the core shaft for driving the first fan and the second fan to assist the heat sink plate for rapidly heat dissipation into the outside open air.

This application claims the priority benefit of Taiwan patent application number 097203941 filed on Mar. 7, 2008.

### BACKGROUND OF THE INVENTION

1. Field of the Invention

The present invention relates to a heat sink module. More particularly, the present invention relates to a heat sink module for producing air circulation to quickly dissipate the heat energy, which comprises a first fan and at least one second fan coaxially connected together for heat dissipation rapidly.

2. Description of Related Art

Along with the rapidly developing technology, the electronic and electrical devices are essential for everyday activities of people's daily lives. Especially, the number of computer users is significantly increasing nowadays. For satisfying the increasing number of computer users, the computer motherboard is upgraded to provide more powerful processing and calculating abilities. The dual-processor chip helps to improve the processing speed to enable the computer to calculate, to process and to execute at a much faster speed. However, the increasing the processing speed correspondingly increases generation of heat energy, and the general method for dissipating the heat energy from the motherboard is to equip the computer with heat sink fins and a fan on the heat source. The heat sink fins are used for absorbing the heat energy from the heat source, and the fan is used for blowing the cold air to the heat sink fins, thus the heat energy absorbed by the heat sink fins can dissipated to the outside. The present installation method includes positioning the fan above the heat sink fins; and therefore when the fan blows the cold air toward the heat sink fins, the different types of heat sink fins will affect the air circulation and the speed of heat dissipation. Therefore, the conventional heat dissipation manner has the following defects.

1. The heat sink fins are designed in different types with different gaps positioning means there-between, and the fan blows the cold air vertically above the heat sink fins, and therefore, the heat dissipation effect is poor at the bottom of the heat sink fins.

2. The heat sink fins are attached to the heat source. In other words, the central region of the bottom portion of the heat sink fins is the hottest region but the cold air from the fan cannot reach easily.

3. The fan usually operates for drawing or blowing air. Although the heat energy can be removed from the heat sink fins, the residual heat still remains on the heat sink fins to affect the heat dissipation efficiency.

Therefore, how to solve the above defects has become the important issue for the suppliers in the field.

### SUMMARY OF THE INVENTION

An object of the present invention is to provide a heat sink module capable of rapidly dissipating the heat.

According to an aspect of the present invention, the heat sink module comprises a heat sink plate which has a chassis for attaching to a heat source, a plurality heat sink fins and a receiving space, and an fan assembly positioned near the receiving space for heat dissipation into the outside open air. The fan assembly comprises a first fan, at least one second fan received in the receiving space and connected to the first fan by a core shaft extending downwardly from the first fan, and a drive unit connected with the core shaft for driving the first fan and the second fan to rotate. Thus, the heat energy can be rapidly dissipated from the heat sink plate into the outside.

According to another aspect of the present invention, the heat sink plate comprises a closed receiving space at a central region of the heat sink fins, which has a closed outer sidewall and a plurality of through holes cut around the outer sidewall. The heat sink module of the present invention further comprises a case covered along the peripheral of the heat sink fins. When the first fan and the second fan of the fan assembly are driven by the drive unit to rotate, the second fan in the closed receiving space could move the heat energy toward the heat sink fins, and the barricade formed by the case provides a chimney effect between the plurality of heat sink fins to enable the heat air to go upward to further allow the first fan to draw the heat air for dissipation into the outside open air.

### BRIEF DESCRIPTION OF THE DRAWING

FIG. 1 is an exploded view of a heat sink module according to an embodiment of the present invention.

FIG. 2 is a sectional side view of FIG. 1.

FIG. 3 is a sectional side view of a heat sink module according to a preferred embodiment of the present invention, showing a case covered on the heat sink plate.

FIG. 4 is a sectional side view of a heat sink module according to alternate embodiment of the present invention.

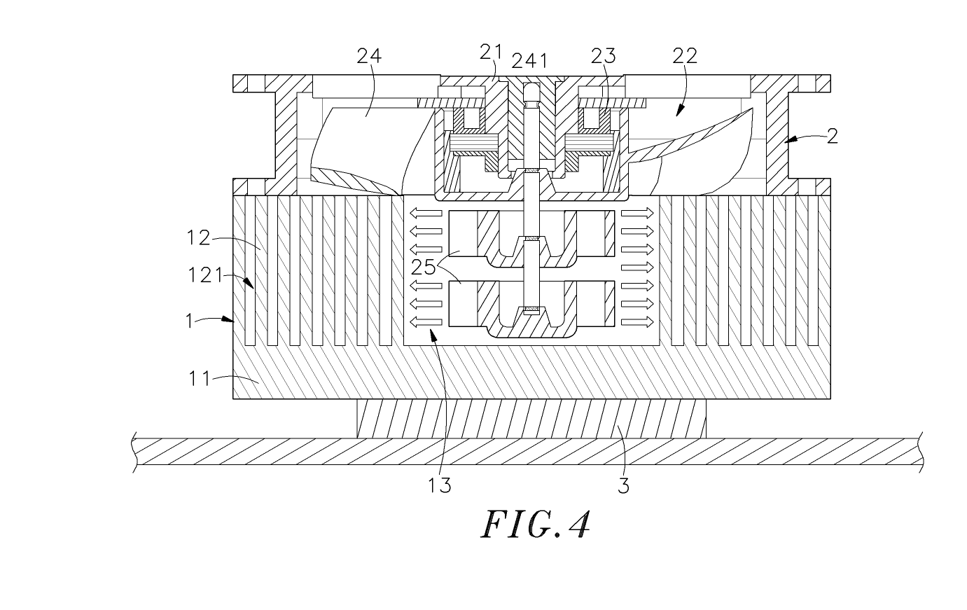

FIG. 5 is an exploded view of a heat sink module according to still another embodiment of the present invention.

FIG. 6 is a sectional side view of FIG. 5.

FIG. 7 is an exploded view of a heat sink module according to still another embodiment of the present invention.

FIG. 8 is a sectional side view of FIG. 7.

### DETAIL DESCRIPTION OF THE INVENTION

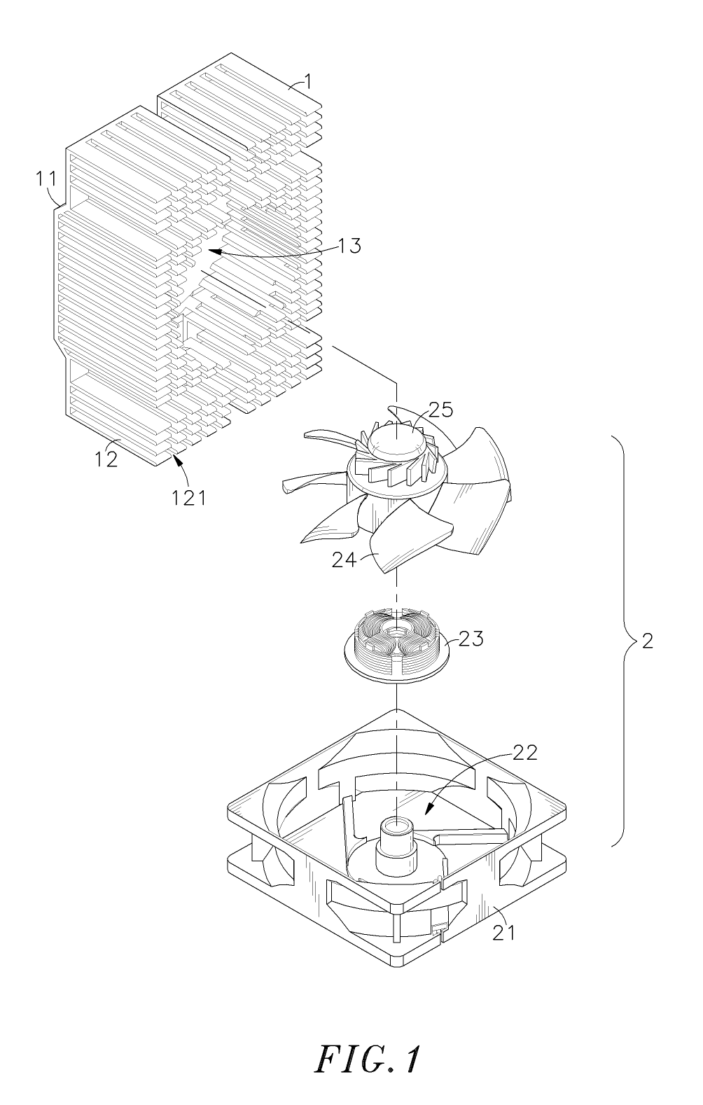

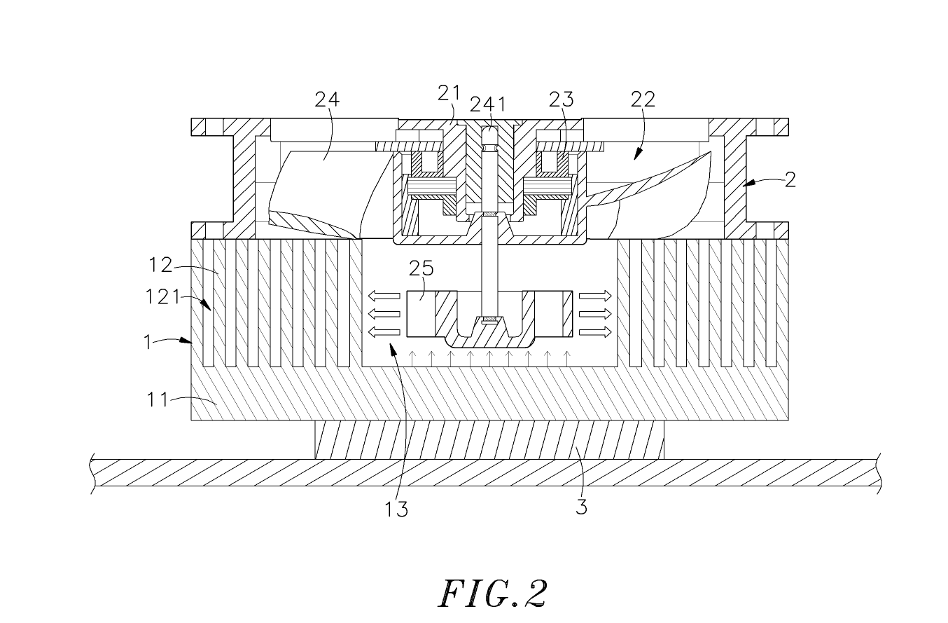

Referring to FIGS. 1 and 2, a heat sink module in accordance with the present invention is shown comprised of a heat sink plate 1 and a fan 2 assembly.

The heat sink plate 1 comprises a chassis 11, a plurality of heat sink fins 12 positioned above, and a receiving space 13 formed at the central region of the heat sink fins 12. The adjacent heat sink fins 12 have a gap 121 in communication with the receiving space 13.

The fan assembly 2 comprises a fan body 21, an accommodation chamber 22 defined within the fan body 21, a drive unit 23 positioned in the accommodation chamber 22, a first fan 24 having a plurality of radial blades, and a second fan 25 mounted on the first fan 24. The first fan 24 comprise a core shaft 241 extending downwardly for connecting with the drive unit 23, thus, the second fan 25 and the first fan 24 are coaxially connected by the core shaft 241 to enable the second 25 rotate along with the first fan 24.

During installation of the present invention, the drive unit 23, the first fan 24 and the second fan 25 are positioned in the accommodation chamber 22 of the fan assembly 2, then, the fan body 21 with the drive unit 23, the first fan 24 and the second fan 25 is capped on the heat sink fins 12 of the heat sink plate 1 to receive the second fan 25 in the receiving space 13 and to have the first fan 24 positioned above the receiving space 13 near the heat sink fins 12.

To operate the heat sink module of the present invention, the chassis 11 of the heat sink plate 1 can be affixed or assembled on a heat source 3 of a mainboard. When the heat source 3 generates heat energy, the plurality of heat sink fins 12 absorb the heat energy from the heat source 3, and the drive unit 23 of the fan assembly 2 drives the first fan 24 and the second fan 25 to rotate. The second fan 25 directly blows the cold air into the receiving space 13 where it is the hottest region in the heat sink plate 1 and blows the heat air out of the heat sink fins 12. Meanwhile, the first fan 24 positioned above the receiving space 13 near the heat sink fins 12 also rotate for dissipation the heat energy away from the heat sink fins 12 into the outside open air. Therefore, the first fan 24 and the second fan 25 can coordinate with each other to rapidly dissipate the heat energy away from the heat sink fins 12 by blowing and drawing air to substantially cool down the hottest region in the heat sink plate 1.

The first fan 24 of the fan 2 can be not only blowing air but also drawing air, and is coaxially connected with the second fan 25 by the core shaft 241. Therefore, the first fan 24 and the second fan 25 can rapidly dissipate the heat energy away from the heat sink plate 1 by blowing and drawing air.

The shape of the heat sink plate 1 can be rectangle, circle or other shapes, and the receiving space 13 at the central region is used to receive the second fan 25 of the fan assembly 2 after installing.

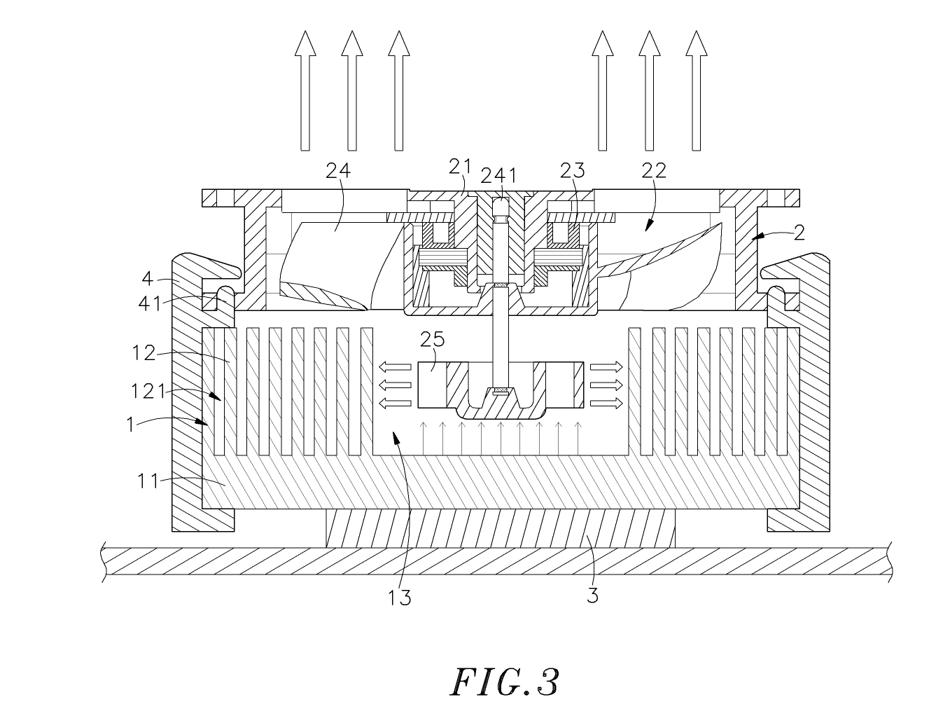

Referring FIGS. 3˜4 and 1 again, a case 4 comprises at least two buckling portions 41 for engagement with the fan assembly 2 to further cover the outline of the heat sink plate 1. When the second fan 25 blows the cold air to the heat sink fins 12, the barricade formed by the case 4 provides a chimney effect to allow the first fan 24 near the receiving space 13 to draw the heat air for dissipation into the outside open air, and thereby prevent the heat air from flowing along the gaps 121 of the heat sink fins 12 to affect the surrounding components. Therefore, the heat dissipation direction can be substantially and effectively controlled.

Besides, the core shaft 241 of the first fan 24 can be used to joint two (or at least one) second fans 25 to increase the wind power to blow the cold air to the plurality of heat sink fins 12, and thereby effectively increase the heat dissipation effect of the heat sink plate 1. When rotating the second fans 25, the cold air flows over not only the hottest region at the bottom of the receiving space 13, but also the gaps 121 between the plurality of the heat sink fins 12. Meanwhile, the first fan 24 positioned above the indented space 13 near the plurality of heat sink fins 12 absorbs the heat energy from the heat sink fins 12. Thus, the heat sink plate 1 can dissipate the heat energy from the heat source 3 effectively.

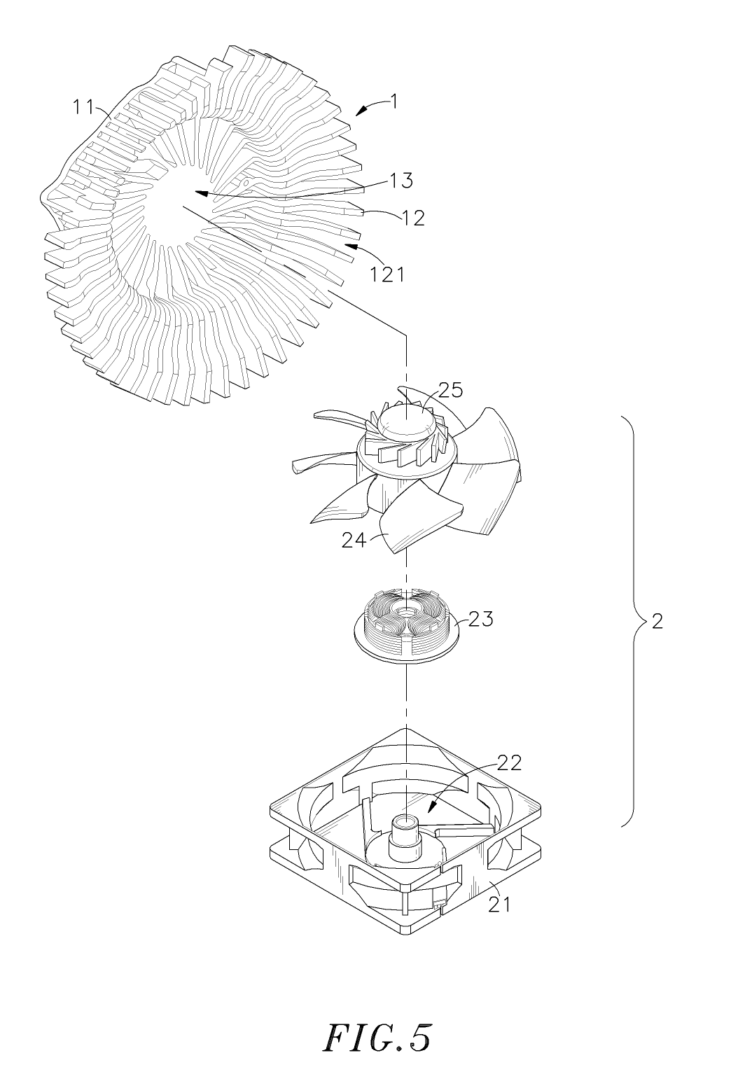

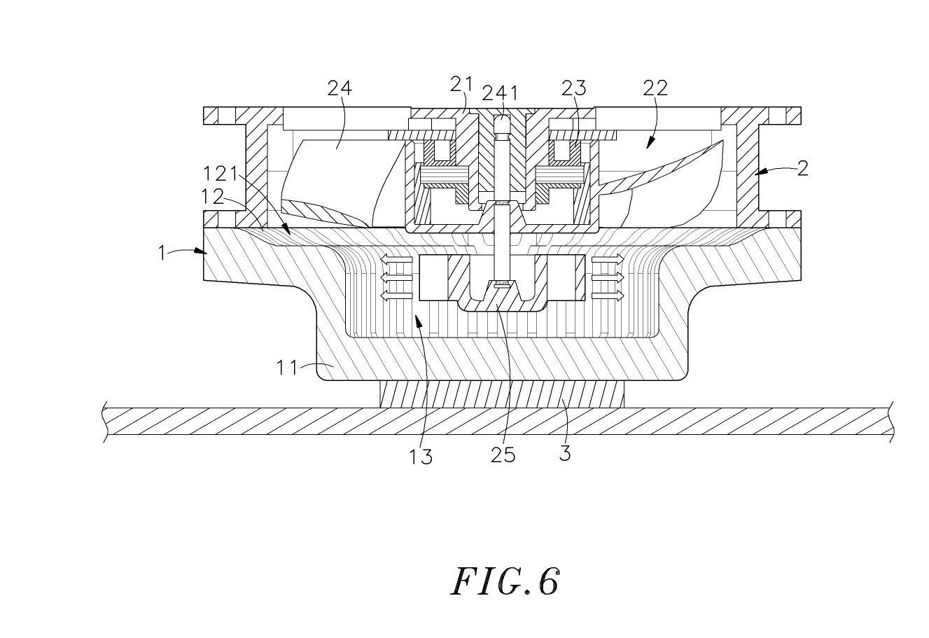

FIGS. 5 and 6 show still another form of the present invention. The embodiment is substantially similar to the embodiment shown in FIG. 1 with exception that the heat sink plate 1 and the fan body 21 of the fan assembly 2 are a circular shape respectively. The circular heat sink plate 1 comprises a receiving space 13 at a center, and a plurality of heat sink fins 12 radially positioned extending from the receiving space 13. The second fan 25 of the fan assembly 2 can be received in the receiving space 13. After the first fan 24 and the second fan 25 are driven by the drive unit 23 to rotate, the circulative air current is flowing around the inner side of the receiving space 13 and the first fan 24 is used to draw the heat air from the receiving space 13 to substantially assist the heat dissipation of the heat sink plate 1.

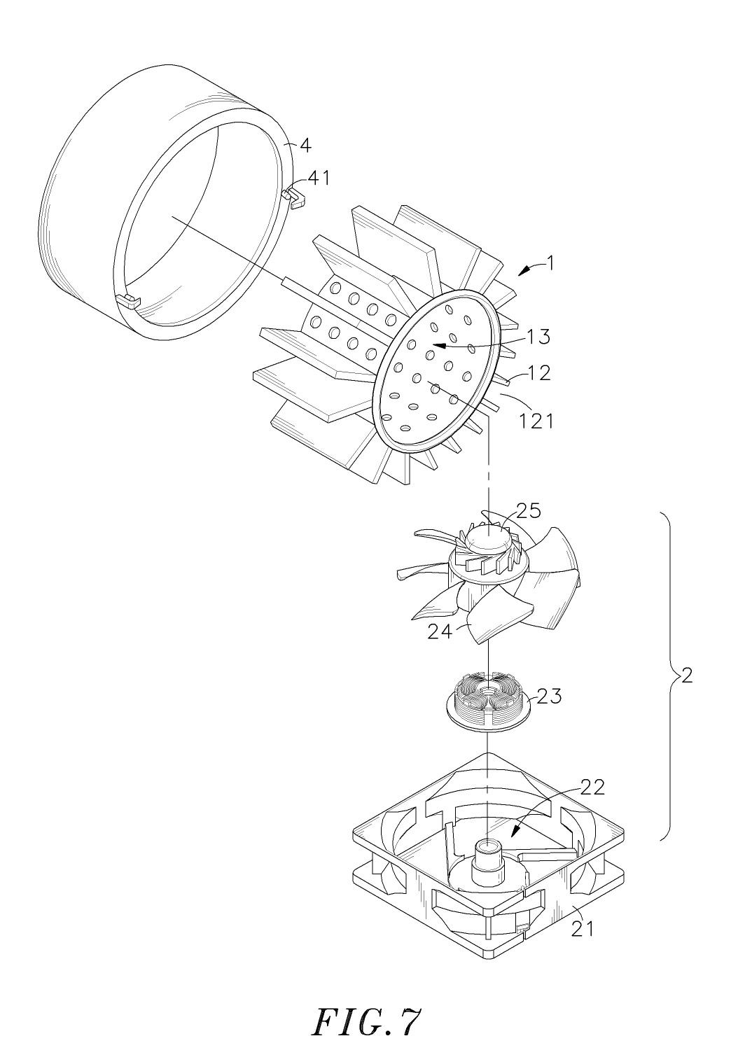

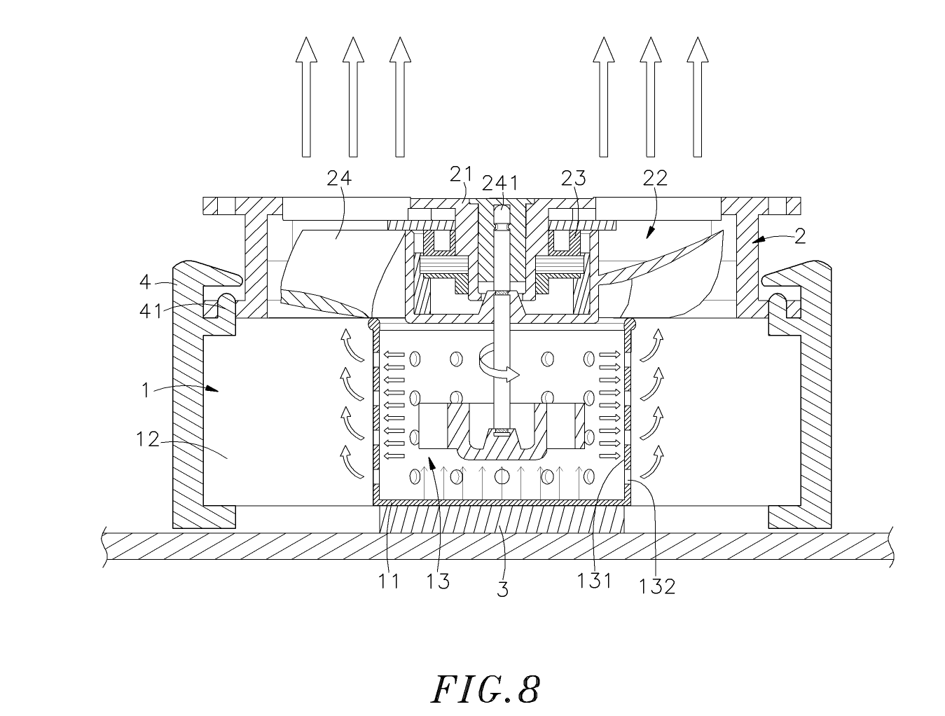

FIGS. 7 and 8 show still another form of the present invention. According to this embodiment, the heat sink plate 1 comprises a closed receiving space 13 at the center thereof, which has a closed outer sidewall 131 and a plurality of through holes 132 on the outer sidewall 131. When the second fan 25 of the fan assembly 2 is received in the closed receiving space 13, the drive unit 23 can drive the first fan 24 and the second fan 25 to draw and blow air current respectively. The cold air from the second fan 25 in the closed receiving space 13 flows through the through holes 132 of the outer sidewall 131 to outside, and further the first fan 24 draws the heat air for dissipation into the outside open air.

Besides, a case 4 may surround along the peripheral of the heat sink plate 1. When driving the second fan 25 in the closed receiving space 13 to rotate, the cold air flows through the through holes 132 of the outer sidewall 131 to outside and is blocked by the case 4. The barricade formed by the case 4 provides a chimney effect between the plurality of heat sink fins 12 to enable the heat air to go upward to further allow the first fan 24 to draw the heat air for dissipation into the outside open air.

As stated above, the invention provides a heat sink module, which comprises a heat sink plate 1 and a fan assembly 2 for heat dissipation. The heat sink plate 1 comprises a chassis 11, a plurality of heat sink fins 12 positioned on the chassis 11, and a receiving space 13 at the central region of the heat sink fins 12 for receiving a second fan 25 connected with a first fan 24 of the fan assembly 2. The first fan 24 and the second fan 25 of the fan assembly 2 can blow and draw air together to assist the heat sink plate 1 to achieve rapid heat dissipation. Besides, a case 4 may cover along the outline of the heat sink plate 1 to provide a chimney effect, and the rising heat air from the plurality of heat sink fins 12 can be drawn by the first fan 24 to the outside open air.

Accordingly, the present invention has at least following advantages.

1. The heat sink plate 1 has a receiving space 13 at the central region of the plurality of heat sink fins 12 for receiving the second fan 25. The second fan 25 can blow the cold air toward the central region of the heat sink plate 1 directly, and the first fan 24 can draw the heat air for heat dissipation coordinately. Thus, the heat energy can be rapidly dissipated from the heat sink plate 1.

2. The first fan 24 can draw the heat air and the second fan 25 can blow the cold air to assist the heat sink plate 1 for heat dissipation rapidly.

3. By covering a case 4 on the outline of the heat sink plate 1, a chimney effect will form between the plurality of heat sink fins 12, and the first fan 24 can draw the rising heat air for dissipation.

4. The heat sink plate 1 comprises a closed receiving space 13, which has a closed outer sidewall 131 and a plurality of through holes 132 cut around the outer sidewall 131. At the same time, a case 4 is covered on the peripheral of the heat sink plate 1. Thus, a chimney effect will form between the plurality of heat sink fins 12, and the first fan 24 can draw the rising heat air for dissipation.

Although particular embodiments of the invention has been described in detail for purposes of illustration, various modifications and enhancements may be may without departing from the spirit and scope of the invention. Accordingly, the invention is not to be limited except as by the appended claims.

What the invention claimed is:

1. A heat sink module for heat dissipating, comprising
a heat sink plate, installed above a heat source, comprising a plurality of heat sink fins and a receiving space; and
a fan assembly, positioned near said receiving space of said heat sink plate, comprising a first fan adjacent to said receiving space and said heat sink fins for heat dissipation, at least one second fan received in said receiving space and coaxially connected to said first fan by a core shaft extending downwardly from said first fan, and a drive unit connected to said core shaft for driving said first fan and said second fan.

2. The heat sink module according to claim 1, wherein said receiving space of said heat sink plate is formed at a central region of said heat sink fins.

3. The heat sink module according to claim 1, wherein said first fan can be a drawing fan for heat dissipation into the outside open air.

4. The heat sink module according to claim 1, wherein said first fan can be a blowing fan for flowing the cold air toward said heat sink plate.

5. The heat sink module according to claim 1, wherein said first fan of said fan assembly positioned above said receiving space and said heat sink fins can draw the heat air for heat dissipation, and said at least one second blades coaxially connected to said first fan can blows the cold air toward said heat sink fins coordinately.

6. The heat sink module according to claim 1, wherein said fan assembly comprises an accommodation chamber for receiving said drive unit and said first fan connected to said drive unit.

7. The heat sink module according to claim 1, further comprising a case, which has at least two buckling portions at top side for buckling with said fan assembly to cover along said heat sink fins to form a barricade.

8. A heat sink module for heat dissipating, comprising
a heat sink plate, installed above a heat source, comprising a plurality of heat sink fins and a closed receiving space which has a closed outer sidewall and a plurality of through holes cut around said outer sidewall;
a case, covered at an outline of said heat sink plate for barricading said plurality of heat sink fins of said heat sink plate; and
a fan assembly, positioned near said closed receiving space of said heat sink plate, comprising a first fan adjacent to said closed receiving space and said heat sink fins for heat dissipation, at least one second fan received in said closed receiving space and coaxially connected to said first fan by a core shaft extending downwardly from said first fan, and a drive unit connected to said core shaft for driving said first fan and said second fan.

9. The heat sink module according to claim 8, wherein said closed receiving space of said heat sink plate is formed at a central region of said heat sink fins.

10. The heat sink module according to claim 8, wherein said first fan can be a drawing fan for heat dissipation into the outside open air.

11. The heat sink module according to claim 8, wherein said first fan can be a blowing fan for flowing the cold air toward said heat sink plate.

12. The heat sink module according to claim 8, wherein said first fan of said fan assembly positioned above said closed receiving space and said heat sink fins can draw the heat air for heat dissipation, and said at least one second blades coaxially connected to said first fan can blows the cold air toward said heat sink fins coordinately.

13. The heat sink module according to claim 8, wherein said fan assembly comprises an accommodation chamber for receiving said drive unit and said first fan connected to said drive unit.

14. The heat sink module according to claim 8, wherein said case has at least two buckling portions at top side for buckling with said fan assembly.
